(19) United States
(12) Patent Application Publication
(10) Pub. No.: US 2026/0211052 A1
(43) Pub. Date: Jul. 23, 2026

(54) DEGRADATION DIAGNOSIS DEVICE, DEGRADATION DIAGNOSIS SYSTEM, AND DEGRADATION DIAGNOSIS METHOD

(71) Applicant: Mitsubishi Electric Corporation, Tokyo (JP)

(72) Inventors: Satoshi HARA, Tokyo (JP); Tomoki TAKEGAMI, Tokyo (JP); Seiji HIRAI, Tokyo (JP); Hiroto NISHIGUCHI, Tokyo (JP)

(73) Assignee: Mitsubishi Electric Corporation, Tokyo (JP)

(21) Appl. No.: 19/138,267

(22) PCT Filed: Mar. 31, 2023
(86) PCT No.: PCT/JP2023/013474

§ 371 Date: Jun. 12, 2025

(51) Int. Cl. G01R 31/392; G01R 31/367; G01R 31/389

(52) U.S. Cl. CPC G01R 31/392; G01R 31/367; G01R 31/389

(57) ABSTRACT

A degradation diagnosis device includes a resistance calculation unit, a capacity calculation unit, a correlation determination unit configured to determine a correlation, and a capacity estimation unit configured to estimate the capacity of the storage battery between an (x−1)-th use and an x-th use of the storage battery system based on the correlation. The resistance calculation unit calculates the resistance a plurality of times in a pre-estimation interval up to the (x−1)-th use of the storage battery system and calculates the resistance in the capacity estimation interval, the correlation determination unit determines the correlation based on the resistance calculated in the pre-estimation interval and the capacity calculated in at least two uses of the storage battery system among a first use to the (x−1)-th use, and the capacity estimation unit estimates the capacity of the storage battery based on the correlation and the resistance calculated in the capacity estimation interval.

### TECHNICAL FIELD

The present disclosure relates to a degradation diagnosis device, a degradation diagnosis system, and a degradation diagnosis method.

### BACKGROUND ART

In a data center or the like, a storage battery system as an emergency power supply is provided to supply electric power to each device in an emergency when electric supply from a power system is cut off. For example, an uninterruptible power supply (UPS) is used as the storage battery system.

To reliably supply electric power from the storage battery system to each device of the data center in an emergency, it is necessary to diagnose the degradation of the storage battery system and grasp the replacement time of the storage battery system. Patent Document 1 discloses a capacity estimation method and a degradation diagnosis device of a battery pack as an emergency power supply.

### CITATION LIST

### Patent Documents

Patent Document 1: Japanese Unexamined Patent Application, First Publication No. 2003-22844

### SUMMARY OF INVENTION

### Problem to be Solved by the Invention

To diagnose the degradation of the storage battery system, it is considered to stop the data center and forcibly discharge the storage battery system to check the capacity of the storage battery of the storage battery system. In this case, it is necessary to stop the data center for a long time, and there is a possibility of hindering the operation of the data center. In addition, the timing of performing the degradation diagnosis of the storage battery system is limited.

In Patent Document 1, internal resistances and capacities of at least two single batteries among a plurality of single batteries constituting a battery pack are measured, and a linear expression representing a correlation between the internal resistance and the capacity is determined based on the measurement results. The capacity of the battery pack is estimated by introducing the internal resistance of the other single battery into this linear expression. In the structure of Patent Document 1, it is necessary to acquire data for degradation diagnosis such as a correlation between the internal resistance and the capacity of the storage battery in advance.

The present disclosure has been made to solve the above-described issues, and an object of the present disclosure is to provide a degradation diagnosis device, a degradation diagnosis system, and a degradation diagnosis method capable of performing degradation diagnosis of a storage battery system at any timing without acquiring data for degradation diagnosis in advance.

### Means to Solve the Problem

A degradation diagnosis device according to the present disclosure is a degradation diagnosis device that diagnoses degradation of a storage battery system, and includes a resistance calculation unit configured to calculate a resistance of a storage battery of the storage battery system, a capacity calculation unit configured to calculate a capacity of the storage battery during use of the storage battery system, a correlation determination unit configured to determine a correlation between the resistance and the capacity of the storage battery based on the resistance calculated by the resistance calculation unit and the capacity calculated by the capacity calculation unit, and a capacity estimation unit configured to estimate the capacity of the storage battery in a capacity estimation interval between an (x−1)-th use and an x-th use of the storage battery system based on the correlation, where x is an integer of 3 or more, in which the resistance calculation unit calculates the resistance a plurality of times in a pre-estimation interval up to the (x−1)-th use of the storage battery system and calculates the resistance in the capacity estimation interval, the correlation determination unit determines the correlation based on the resistance calculated by the resistance calculation unit in the pre-estimation interval and the capacity calculated by the capacity calculation unit in at least two uses of the storage battery system among a first use to the (x−1)-th use, and the capacity estimation unit estimates the capacity of the storage battery based on the correlation and the resistance calculated by the resistance calculation unit in the capacity estimation interval.

A degradation diagnosis system according to the present disclosure includes the degradation diagnosis device and the storage battery system, in which the storage battery system includes a storage battery and a storage battery control unit configured to control the storage battery.

A degradation diagnosis method according to the present disclosure is a degradation diagnosis method for diagnosing degradation of a storage battery system, and includes a resistance calculation step of calculating a resistance of a storage battery of the storage battery system, a capacity calculation step of calculating a capacity of the storage battery during use of the storage battery system, a correlation determination step of determining a correlation between the resistance and the capacity of the storage battery based on the resistance calculated in the resistance calculation step and the capacity calculated in the capacity calculation step, and a capacity estimation step of estimating the capacity of the storage battery in a capacity estimation interval between an (x−1)-th use and an x-th use of the storage battery system based on the correlation, where x is an integer of 3 or more, in which in the resistance calculation step, the resistance is calculated a plurality of times in a pre-estimation interval up to the (x−1)-th use of the storage battery system and the resistance is calculated in the capacity estimation interval, in the correlation determination step, the correlation is determined based on the resistance calculated in the resistance calculation step in the pre-estimation interval and the capacity calculated in the capacity calculation step in at least two uses of the storage battery system among a first use to the (x−1)-th use, and in the capacity estimation step, the capacity of the storage battery is estimated based on the correlation and the resistance calculated in the resistance calculation step in the capacity estimation interval.

### Effects of the Invention

According to the present disclosure, it is possible to provide a degradation diagnosis device, a degradation diagnosis system, and a degradation diagnosis method capable of performing degradation diagnosis of a storage battery system at any timing without acquiring data for degradation diagnosis in advance.

### BRIEF DESCRIPTION OF DRAWINGS

FIG. 1A A diagram showing the overall configuration of a data center according to a first embodiment in a normal time.

FIG. 1B A diagram showing an overall configuration of the data center according to the first embodiment in an emergency.

FIG. 2A block diagram of a UPS, an operation unit, and a display unit according to the first embodiment.

FIG. 3A graph showing a transition of an SOC of a storage battery according to a change in a usage state of the UPS.

FIG. 4A diagram showing calculation of the resistance and the capacity of a storage battery and estimation of the capacity of the storage battery by an operation unit according to the first embodiment.

FIG. 5A A graph showing an example of a voltage curve in a case where the UPS is used from an upper limit voltage to a lower limit voltage.

FIG. 5B A graph showing an example of a current curve in a case where the UPS is used from the upper limit voltage to the lower limit voltage.

FIG. 5C A graph showing an example of an SOC curve in a case where the UPS is used from the upper limit voltage to the lower limit voltage.

FIG. 6 A diagram showing estimation of the capacity of a storage battery by the operation unit according to the first embodiment.

FIG. 7 A flowchart showing an example of processing executed by the degradation diagnosis device according to the first embodiment.

FIG. 8 A diagram showing estimation of the capacity of a storage battery by the operation unit according to a second embodiment.

FIG. 9 A diagram showing calculation of the resistance and the capacity of a storage battery and estimation of the capacity of the storage battery by an operation unit according to a third embodiment.

FIG. 10A A graph showing the normal distribution of a resistance estimation error.

FIG. 10B A graph showing the normal distribution of a capacity estimation error.

FIG. 11 A diagram showing estimation of the capacity of a storage battery by the operation unit according to the third embodiment.

FIG. 12 A diagram showing estimation of the capacity of a storage battery by the operation unit according to a fourth embodiment.

FIG. 13 A graph showing a transition of the capacity retention ratio of a storage battery.

### DESCRIPTION OF EMBODIMENTS

Hereinafter, embodiments of the present disclosure will be described with reference to drawings. The scope of the present disclosure is not limited to the following embodiments, and can be changed in any way within the scope of technical ideas of the present disclosure.

### First Embodiment

First, a degradation diagnosis device, a degradation diagnosis system, and a degradation diagnosis method according to a first embodiment will be described. The degradation diagnosis device according to the present embodiment is installed in the data center 1.

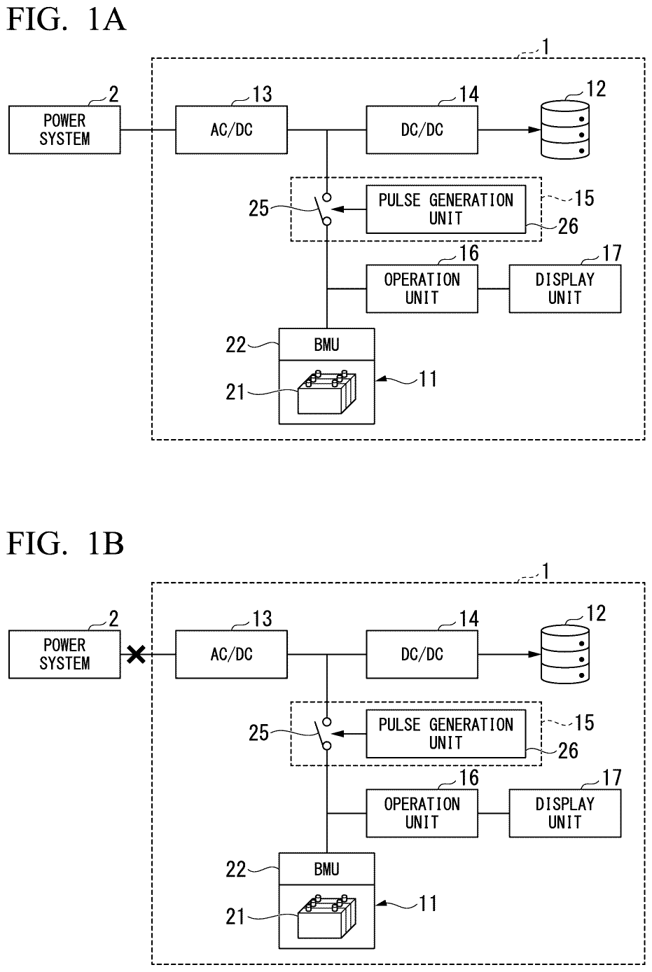

FIGS. 1A and 1B are diagrams showing the overall configuration of a data center 1. As shown in FIGS. 1A and 1B, the data center 1 is constituted by an uninterruptible power supply (UPS) 11, a server storage 12, an AC/DC converter 13, a DC/DC converter 14, a pulse generation device 15, an operation unit 16, a display unit 17, and the like. The data center 1 is connected to the power system 2. The UPS 11 is an example of a storage battery system. The pulse generation device 15, the operation unit 16, and the display unit 17 constitute a degradation diagnosis device that diagnoses degradation of the UPS 11. The UPS 11, the pulse generation device 15, the operation unit 16, and the display unit 17 constitute a degradation diagnosis system.

The server storage 12 is a device for storing data for a long period of time. The server storage 12 is used in a device such as a computer or data communication. The server storage 12 is connected to the power system 2 via the AC/DC converter 13 and the DC/DC converter 14. The server storage 12 is connected to the UPS 11 via a DC/DC converter 14. In a normal time, the server storage 12 is supplied with power by the power system 2. In this case, the UPS 11 is not used and is in a standby state. In an emergency in which the electric supply from the power system 2 to the server storage 12 is cut off, the server storage 12 is supplied with power by the UPS 11. Hereinafter, the normal time will also be referred to as a time when the UPS 11 is not in use. The emergency is also referred to as a case where the UPS 11 is in use.

The UPS 11 includes a storage battery 21 and a battery management unit (BMU) 22 (storage battery control unit).

The storage battery 21 is a secondary battery that is capable of charging and discharging. The storage battery 21 is, for example, a lithium ion battery, a nickel hydrogen battery, or a lead storage battery.

The BMU 22 controls charging and discharging of the storage battery 21. The BMU 22 has a protection function of preventing overcharging, overdischarging, overvoltage, overcurrent, temperature abnormality, and the like of the storage battery 21 based on the upper and lower limit voltages, the maximum charging and discharging current, the maximum cell temperature, and the like of the storage battery 21. The BMU 22 has a state monitoring function of the storage battery 21, such as voltage measurement, current measurement, power measurement, temperature measurement, full charge management, and remaining capacity management of the storage battery 21. The UPS 11 is provided with a measurement sensor that measures a voltage, a current, and a temperature of the storage battery 21. The measurement sensor includes, for example, a voltage probe for measuring a voltage of the storage battery 21, a shunt resistor type or a hall type current sensor for measuring a current of the storage battery 21, and a thermocouple for measuring a temperature of the storage battery 21.

The UPS 11 is connected to the power system 2. In a normal time (that is, in a case where the UPS 11 is not in use), the UPS 11 is constantly charged by the power system 2.

FIG. 3 is a diagram showing a transition of a state of charge (SOC) of the storage battery 21 according to a change in a usage state of the UPS 11. A case where the SOC is 0(%) indicates that the storage battery 21 is in a completely discharged state, and a case where the SOC is 100(%) indicates that the storage battery 21 is in a fully charged state.

As shown in FIG. 3, the SOC of the storage battery 21 is divided into a region A1 in which the SOC is retained at 100(%), a region A2 in which the SOC decreases from 100(%) to X (%), and a region A3 in which the SOC recovers from X (%) to 100(%).

The region A1 corresponds to a case where the UPS 11 is not in use. In this case, the storage battery 21 is not used for electric supply to the server storage 12, and is charged by the power system 2 to retain a fully charged state.

The region A2 corresponds to a case where the UPS 11 is in use. In this case, the electric supply from the power system 2 to the server storage 12 is cut off. The storage battery 21 is discharged to supply power to the server storage 12, and the SOC of the storage battery 21 is decreased.

The region A3 corresponds to a case where the UPS 11 is not in use. In the region A3, the power system 2 is restored, and the electric power supply to the server storage 12 is switched from the UPS 11 to the power system 2. The storage battery 21 is charged by the power system 2 to return to a fully charged state.

The regions A1 to A3 are repeated depending on the use of the UPS 11.

It is noted that in the data center 1, in a case where the power system 2 is restored, since electric supply to the server storage 12 is switched from the UPS 11 to the power system 2, use of the UPS 11 is often terminated before the storage battery 21 is completely discharged (that is, before the SOC is lowered to 0(%)). FIG. 3 shows a case where the SOC of the storage battery 21 is decreased to X (%) in the region A2, but the value of X varies depending on the time during which the electric supply from the power system 2 to the server storage 12 is cut off. In addition, in the data center 1, since the UPS 11 is used only in an emergency, the UPS 11 is used infrequently and often stands in a fully charged state (that is, in the area A1).

The AC/DC converter 13 converts the alternating current power from the power system 2 into direct current power.

The DC/DC converter 14 converts the voltage of the electric power from the UPS 11 into a voltage corresponding to the server storage 12. The DC/DC converter 14 converts the voltage of the electric power from the power system 2 into a voltage corresponding to the server storage 12.

The pulse generation device 15 is provided between the UPS 11 and the DC/DC converter 14. The pulse generation device 15 switches on and off the conduction of the current between the UPS 11 and the DC/DC converter 14 to switch on and off the discharging from the storage battery 21 of the UPS 11 to the server storage 12. The pulse generation device 15 includes a switch 25 and a pulse generation unit 26.

The pulse generation unit 26 generates a pulse signal for switching between an on state and an off state of the switch 25.

The switch 25 is switched between an on state and an off state by the pulse signal from the pulse generation unit 26 to switch on and off the conduction of the current between the UPS 11 and the DC/DC converter 14.

In a case where the switch 25 is in an on state, the discharge occurs from the UPS 11 to the server storage 12. In a normal time shown in FIG. 1A, in a case where the switch 25 is in an on state, the server storage 12 is supplied with power from both the power system 2 and the UPS 11. In the emergency shown in FIG. 1B, the switch 25 is always in an on state, and the server storage 12 is supplied with power from the UPS 11. In a case where the switch 25 is in an off state, the current is blocked between the UPS 11 and the DC/DC converter 14, and the discharge does not occur from the UPS 11 to the server storage 12.

It is noted that the pulse generation device 15 is only required to be allowed to switch on and off of the discharge from the UPS 11 to the server storage 12, for example, may be constituted by a resistor and a switch. In this case, the resistor is, for example, a variable resistor, and the on and off of the discharge from the UPS 11 to the server storage 12 may be switched by switching the resistance value in a pulsed manner.

The operation unit 16 estimates the capacity of the storage battery 21 in the capacity estimation interval P1 between the (x−1)-th use and the x-th use of the UPS 11, and calculates the capacity retention ratio of the storage battery 21 based on the estimated capacity of the storage battery 21. It is noted that x is an integer of 3 or more. The capacity estimation interval P1 corresponds to a case where the UPS 11 is not in use. In addition, in the following description, an interval from the initial state to the (x−1)-th use of the UPS 11 is referred to as a pre-estimation interval P2. The pre-estimation interval P2 includes the (x−1)-th use of the UPS 11.

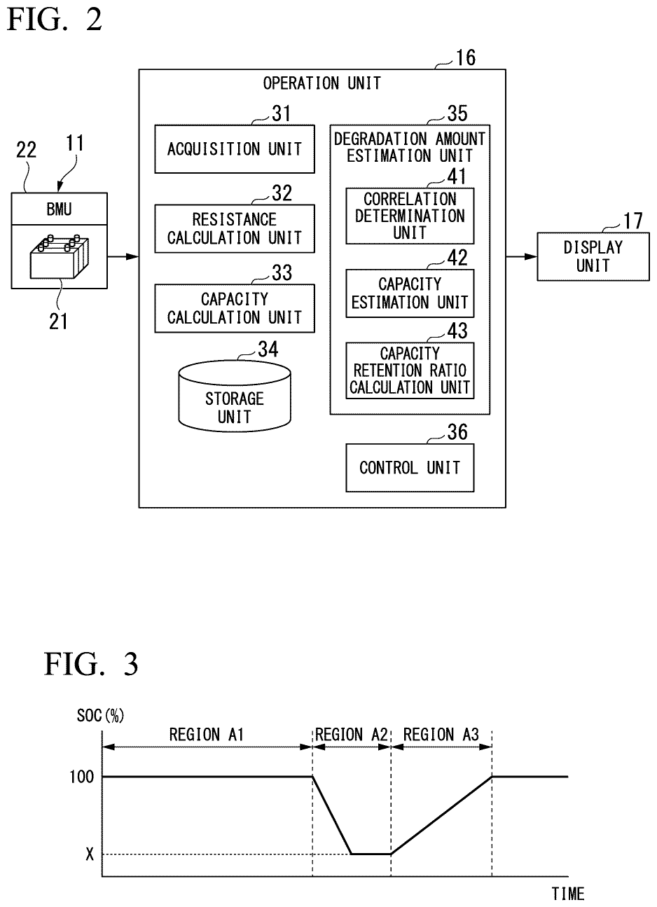

FIG. 2 is a block diagram of the UPS 11, the operation unit 16, and the display unit 17. As shown in FIG. 2, the operation unit 16 includes an acquisition unit 31, a resistance calculation unit 32, a capacity calculation unit 33, a storage unit 34, a degradation amount estimation unit 35, and a control unit 36.

The control unit 36 controls the acquisition unit 31, the resistance calculation unit 32, the capacity calculation unit 33, and the degradation amount estimation unit 35 by executing a program by a central processing unit (CPU) or the like. In addition, the control unit 36 controls the pulse generation device 15. For example, the control unit 36 gives an instruction to the pulse generation device 15 to generate a pulse signal for ordering the storage battery 21 to discharge. It is noted that the control unit configured to control the pulse generation device 15 may be provided separately from the control unit 36.

The acquisition unit 31 acquires the parameter of the storage battery 21 to be used for estimating the capacity of the storage battery 21 from the UPS 11. The parameters of the storage battery 21 include, for example, a current, a voltage, and a temperature of the storage battery 21. The acquisition unit 31 acquires the parameter of the storage battery 21 from the BMU 22. The acquisition unit 31 may acquire the parameter of the storage battery 21 from the measurement sensor provided in the UPS 11 without through the BMU 22.

The resistance calculation unit 32 calculates the resistance of the storage battery 21 based on the parameter of the storage battery 21 acquired by the acquisition unit 31. Specifically, the resistance calculation unit 32 calculates the resistance of the storage battery 21 based on the response of the current and the voltage of the storage battery 21 in a case where the storage battery 21 is discharged. The discharge time of the storage battery 21 for calculating the resistance of the storage battery 21 is, for example, about 1 to 10 seconds. The calculated resistance is stored in the storage unit 34.

The resistance R of the storage battery 21 is calculated from Expression (1) below according to Ohm's law. In Expression (1), I is a current of the storage battery 21 in a case where the storage battery 21 is discharged, and V is a voltage of the storage battery 21 in a case where the storage battery 21 is discharged. The OCV is an open circuit voltage of the storage battery 21. The open circuit voltage of the storage battery 21 is a voltage in a case where the storage battery 21 is left to stand in a no-load state and the voltage is not fluctuated.

$$R ( Ω ) = \frac{OCV ( V ) - V ( V )}{I ( A )} \qquad ( 1 )$$

The resistance of the storage battery 21 changes depending on the temperature of the storage battery 21. Therefore, it is preferable that the temperature of the storage battery 21 in a case of calculating the resistance of the storage battery 21 is constant. In a case where the temperature of the storage battery 21 changes, the resistance calculation unit 32 may correct the resistance of the storage battery 21 according to the change in the temperature of the storage battery 21. For example, a reference temperature may be predetermined, and the resistance calculation unit 32 may correct the resistance of the storage battery 21 according to a difference between the temperature of the storage battery 21 and the reference temperature.

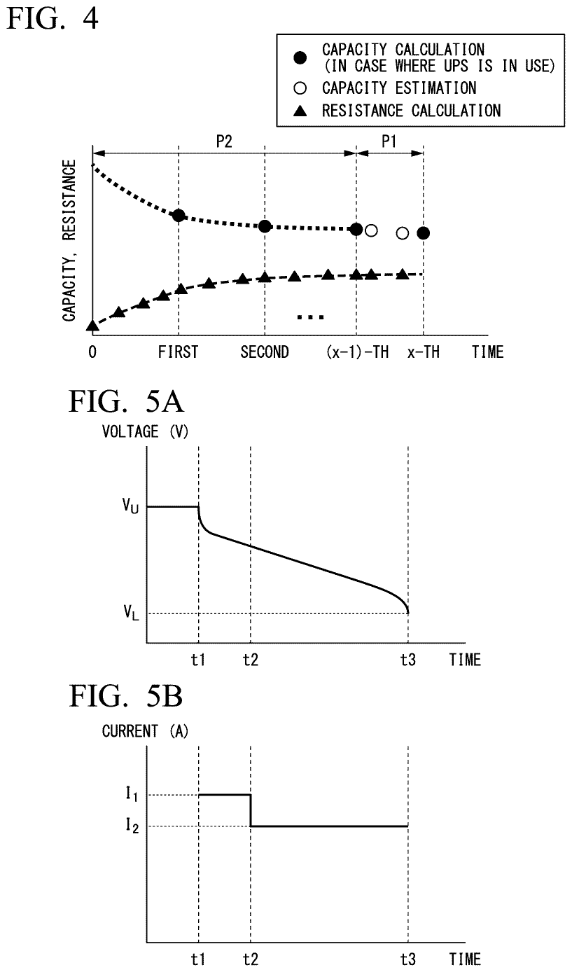

In FIG. 4, the resistance calculated by the resistance calculation unit 32 is represented by a triangle. As shown in FIG. 4, the resistance calculation unit 32 calculates the resistance of the storage battery 21 a plurality of times in the pre-estimation interval P2. In addition, the resistance calculation unit 32 calculates the resistance of the storage battery 21 in the capacity estimation interval P1.

The pre-estimation interval P2 includes a region A2 corresponding to a case where the UPS 11 is in use and regions A1 and A3 corresponding to a case where the UPS 11 is not in use. The resistance calculation unit 32 calculates the resistance of the storage battery 21 in the region A2 and the region A1 in the pre-estimation interval P2. In the region A2 of the pre-estimation interval P2, the resistance calculation unit 32 calculates the resistance of the storage battery 21 according to the response of the current and the voltage of the storage battery 21 in a case where the server storage 12 is supplied with power from the UPS 11. In the region A1 of the pre-estimation interval P2, the resistance calculation unit 32 calculates the resistance of the storage battery 21 according to the response of the current and the voltage of the storage battery 21 in a case where the storage battery 21 is discharged for a predetermined discharge time by the pulse generation device 15. In the region A2, the resistance of the storage battery 21 may not be calculated.

The capacity calculation unit 33 calculates the capacity of the storage battery 21 in a case where the UPS 11 is in use, according to the parameter of the storage battery 21 acquired by the acquisition unit 31. The calculated capacity is stored in the storage unit 34.

In FIG. 4, the capacity calculated by the capacity calculation unit 33 is represented by a black circle. As shown in FIG. 4, the capacity calculation unit 33 calculates the capacity of the storage battery 21 each time the UPS 11 is used.

FIG. 5A is a graph showing a voltage curve in a case where the UPS 11 is used from the upper limit voltage Vu to the lower limit voltage V_{L}. FIG. 5B is a graph showing a current curve in the above case. FIG. 5C is a graph showing an SOC curve in the above case. In FIGS. 5A to 5C, a time point t1 is a time point at which the use of the UPS 11 is started (that is, a time point at which the use of the UPS 11 is switched from normal time to emergency), a time point t2 is a time point at which the current value is changed from I₁ to I₂ because of a change in the use status of the server storage 12 that is the load, and a time point t3 is a time point at which the use of the UPS 11 is ended (that is, a time point at which the use of the UPS 11 is switched from emergency to normal time). As shown in FIGS. 5A to 5C, the voltage, the current, and the SOC of the storage battery 21 are related to each other.

The capacity of the storage battery 21 can be calculated by integrating the current of the storage battery 21. For example, in a case where the SOC of the storage battery 21 changes from 100(%) to 0(%) by using the UPS 11, the capacity Q of the storage battery 21 is calculated as in Expression (2). Specifically, the capacity Q of the storage battery 21 is obtained by integrating the current I in a case where the SOC changes from 100(%) to 0(%). The unit of the capacity Q of the storage battery 21 is Ah or Wh.

$$Q = {\int }_{SOC 0 \%}^{SOC 100 \%} Idt \qquad ( 2 )$$

Here, since the UPS 11 is temporarily used when the power system 2 is cut off, the UPS 11 is rarely used from a fully charged state to a completely discharged state at a constant current or a constant voltage. In a case where the UPS 11 is in use, in a case where the UPS 11 is not used to the completely discharged state and the SOC changes from a (%) to b (%), the capacity Q of the storage battery 21 is calculated as Expression (3). Specifically, the current I of the partial discharge in a case where the SOC changes from a (%) to b (%) is integrated. The capacity Q is obtained by multiplying the integrated result by 100/(a−b).

$$Q = {\int }_{SOCa}^{SOCb} Idt \times \frac{100}{a - b} \qquad ( 3 )$$

The capacity of the storage battery 21 changes depending on the temperature of the storage battery 21. Therefore, it is preferable that the temperature of the storage battery 21 in a case of calculating the capacity of the storage battery 21 is constant. In a case where the temperature of the storage battery 21 changes, the capacity calculation unit 33 may correct the capacity of the storage battery 21 according to the change in the temperature of the storage battery 21. For example, a reference temperature may be predetermined, and the capacity calculation unit 33 may correct the capacity of the storage battery 21 according to a difference between the temperature of the storage battery 21 and the reference temperature.

The resistance calculated by the resistance calculation unit 32 and the capacity calculated by the capacity calculation unit 33 are stored in the storage unit 34 as past data. The storage unit 34 is formed by, for example, a non-volatile or volatile semiconductor memory such as a random access memory (RAM), a read only memory (ROM), a flash memory, an erasable programmable read only memory (EPROM), or an electrically erasable and programmable ROM (EEPROM).

The degradation amount estimation unit 35 estimates the degradation amount of the storage battery 21 based on the resistance of the storage battery 21 calculated by the resistance calculation unit 32 and the capacity of the storage battery 21 calculated by the capacity calculation unit 33. The degradation amount estimation unit 35 includes a correlation determination unit 41, a capacity estimation unit 42, and a capacity retention ratio calculation unit 43.

The correlation determination unit 41 determines a correlation between the resistance and the capacity of the storage battery 21 based on the resistance of the storage battery 21 calculated by the resistance calculation unit 32 and the capacity of the storage battery 21 calculated by the capacity calculation unit 33.

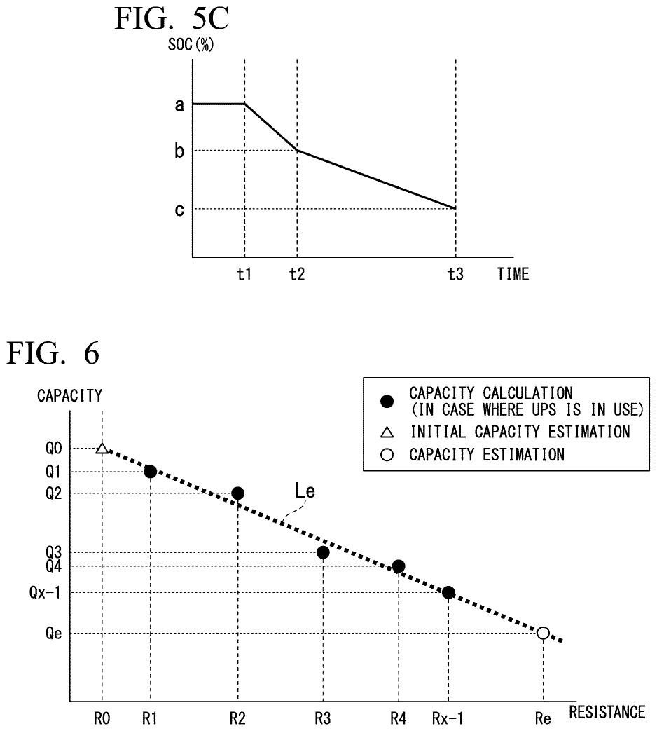

FIG. 6 is a diagram showing the estimation of the capacity of the storage battery 21 by the operation unit 16. In FIG. 6, a vertical axis indicates the capacity of the storage battery 21, and a horizontal axis indicates the resistance of the storage battery 21. Q1, Q2, . . . , and Qx−1 each indicate the capacity of the storage battery 21 calculated by the capacity calculation unit 33 in the first use, the second use, . . . , and (x−1)th use of the UPS 11. R1, R2, . . . , and Rx−1 each indicate the resistance of the storage battery 21 calculated by the capacity calculation unit 33 in the first use, the second use, . . . , and (x−1)th use of the UPS 11. In a case where the resistance of the storage battery 21 is not calculated in the region A2, the resistances R1, R2, . . . , and Rx−1 of the storage battery 21 may be calculated based on the resistance of the storage battery 21 calculated by the resistance calculation unit 32 in the region A1. As shown in FIG. 6, the resistance of the storage battery 21 and the capacity of the storage battery 21 have a correlation. That is, in a case where the UPS 11 is degradated by use and the capacity of the storage battery 21 is decreased, the resistance of the storage battery 21 is increased.

The correlation determination unit 41 determines the correlation between the resistance and the capacity of the storage battery 21 by obtaining the approximate curve Le representing the correlation between the resistance and the capacity of the storage battery 21. For example, in the example of FIG. 6, the approximate curve Le is represented by Expression (4) as a linear function. It is noted that the approximate curve Le may be any function that can indicate the correlation between the resistance and the capacity of the storage battery 21, and is not limited to the linear function.

$${Q}_{x} = {AR}_{x} + B \qquad ( 4 )$$

The correlation determination unit 41 determines the coefficient A and the constant B in Expression (4) based on the resistances R1, R2, . . . , and Rx−1 of the storage battery 21 calculated by the resistance calculation unit 32 and the capacities Q1, Q2, . . . , and Qx−1 of the storage battery 21 calculated by the capacity calculation unit 33. In this case, the correlation determination unit 41 can determine the correlation between the resistance and the capacity of the storage battery 21 by using at least two capacities among the capacities Q1, Q2, . . . , and Qx−1 of the storage battery 21 calculated by the capacity calculation unit 33. To improve the accuracy, it is preferable to determine the correlation between the resistance and the capacity of the storage battery 21 by using three or more capacities among the capacities Q1, Q2, . . . , and Qx−1 of the storage battery 21 calculated by the capacity calculation unit 33.

The capacity estimation unit 42 estimates the capacity of the storage battery 21 in the capacity estimation interval P1 based on the correlation determined by the correlation determination unit 41 and the resistance of the storage battery 21 calculated by the resistance calculation unit 32 in the capacity estimation interval P1. Specifically, the capacity estimation unit 42 estimates the capacity Qe of the storage battery 21 in the capacity estimation interval P1 by introducing the resistance Re of the storage battery 21 calculated by the resistance calculation unit 32 in the capacity estimation interval P1 into Expression (4).

The capacity retention ratio calculation unit 43 calculates the capacity retention ratio of the storage battery 21 based on the capacity Q of the storage battery 21. In a case where the capacity retention ratio of the storage battery 21 in the initial state until the first use of the UPS 11 is set to 100(%) (that is, in a case where the degradation amount of the storage battery 21 is set to 0(%)), the capacity retention ratio M (%) is represented by Expression (5). It is noted that Q₀ is the capacity of the storage battery 21 in the initial state. The capacity Q₀ of the storage battery 21 can be estimated based on the resistances R1, R2, . . . , and Rx−1 of the storage battery 21 calculated by the resistance calculation unit 32 and the capacities Q1, Q2, . . . , and Qx−1 of the storage battery 21 calculated by the capacity calculation unit 33.

$$M = \frac{Q}{{Q}_{0}} \times 100 \qquad ( 5 )$$

In a case where the capacity retention ratio calculated by the capacity retention ratio calculation unit 43 is equal to or less than the threshold value, it is determined that the life of the UPS 11 has arrived. The threshold value may be, for example, 80(%) or 60(%). It is noted that the degradation amount estimation unit 35 may calculate the life of the UPS 11, the replacement time of the UPS 11, or the like based on the capacity retention ratio calculated by the capacity retention ratio calculation unit 43.

The display unit 17 is a display device such as a display. The display unit 17 displays a parameter of the storage battery 21, the capacity of the storage battery 21, the capacity retention ratio of the storage battery 21, and the like. In a case where the degradation amount estimation unit 35 calculates the life or replacement time of the UPS 11, the display unit 17 may display the life or replacement time of the UPS 11.

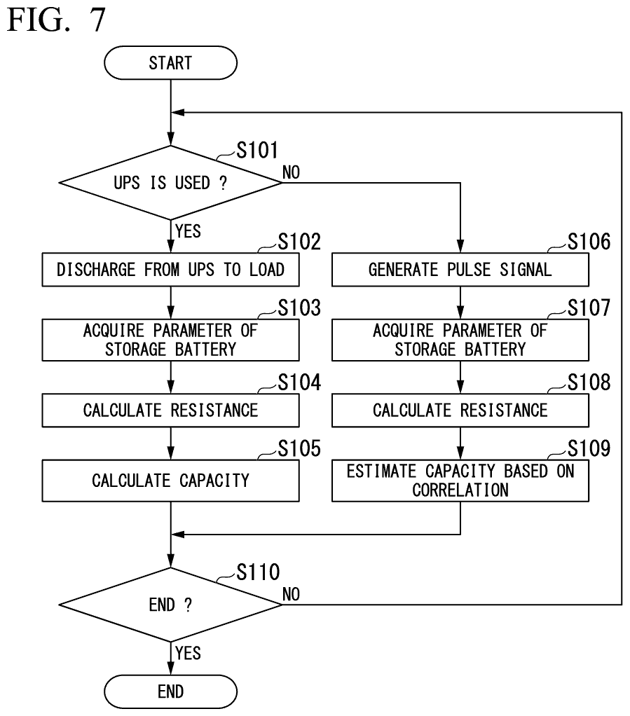

FIG. 7 is a flowchart showing an example of a flow of processing of the degradation diagnosis method of the UPS 11.

First, it is determined whether or not the UPS 11 is being used (Step S101).

In a case where the UPS 11 is used (Step S101: YES), the discharge from the UPS 101 to the server storage 12 as the load is performed (Step S102).

The acquisition unit 31 acquires the parameter of the storage battery 21 in a case where the UPS 11 is in use (Step S103).

The resistance calculation unit 32 calculates the resistance of the storage battery 21 based on the parameter of the storage battery 21 acquired in Step S103 (Step S104). Step S104 corresponds to a resistance calculation step. The calculated resistance of the storage battery 21 is stored in the storage unit 34.

The capacity calculation unit 33 calculates the capacity of the storage battery 21 based on the parameter of the storage battery 21 acquired in Step S103 (Step S105). Step S105 corresponds to the capacity calculation step. The calculated capacity of the storage battery 21 is stored in the storage unit 34.

Thereafter, the processing proceeds to Step S110.

In a case where the UPS 11 is not in use (Step S101: NO), the control unit 36 makes the pulse generation unit 26 of the pulse generation device 15 generate a pulse signal, thereby the storage battery 21 is discharged for a discharge time (Step S106).

The acquisition unit 31 acquires the parameter of the storage battery 21 in a case where the storage battery 21 is discharged by the pulse generation device 15 (Step S107).

The resistance calculation unit 32 calculates the resistance of the storage battery 21 based on the parameter of the storage battery 21 acquired in Step S107 (Step S108). Step S108 corresponds to the resistance calculation step.

The degradation amount estimation unit 35 determines a correlation between the resistance and the capacity of the storage battery 21 based on the resistance of the storage battery 21 calculated in Step S104 and the capacity of the storage battery 21 calculated in Step S105, and estimates the capacity of the storage battery 21 based on the determined correlation and the resistance of the storage battery 21 calculated in Step S108 (Step S109). Step S109 corresponds to a correlation determination step and a capacity estimation step.

Thereafter, the processing proceeds to Step S110.

Thereafter, the control unit 36 determines whether or not to end the degradation diagnosis of the UPS 11 (Step S110). In a case where the determination result in Step S110 is YES, the processing ends. In a case where the determination result in Step S110 is NO, the process returns to Step S101. For example, a case where it is preferable to continue the estimation of the capacity of the storage battery 21 is determined as Step S110: NO. A case where the state of the storage battery 21 can be sufficiently grasped is determined as Step S110: YES, and the processing ends.

As described above, the degradation diagnosis device according to the present embodiment includes the resistance calculation unit 32 that calculates the resistance of the storage battery 21 of the UPS 11, the capacity calculation unit 33 that calculates the capacity of the storage battery 21 in a case where the UPS 11 is in use, the correlation determination unit 41 that determines the correlation between the resistance and the capacity of the storage battery 21 based on the resistance calculated by the resistance calculation unit 32 and the capacity calculated by the capacity calculation unit 33, and the capacity estimation unit 42 that estimates the capacity of the storage battery 21 in the capacity estimation interval P1 between the (x−1)-th use and the x-th use of the UPS 11 based on the correlation. Provided that x is an integer of 3 or more. The resistance calculation unit 32 calculates the resistance a plurality of times in the pre-estimation interval P2 before the (x−1)-th use of the UPS 11 and calculates the resistance in the capacity estimation interval P1. The correlation determination unit 41 determines a correlation based on the resistance calculated by the resistance calculation unit 32 in the pre-estimation interval P2 and the capacity calculated by the capacity calculation unit 33 in at least two uses of the UPS 11 among a first use to the (x−1)-th use. The capacity estimation unit 42 estimates the capacity of the storage battery 21 based on the correlation and the resistance calculated by the resistance calculation unit 32 in the capacity estimation interval P1.

In addition, the degradation diagnosis system according to the present disclosure includes the degradation diagnosis device and the UPS 11. The UPS 11 includes a storage battery 21 and a BMU 22 that controls the storage battery 21.

In addition, the degradation diagnosis method according to the present embodiment includes a resistance calculation step of calculating the resistance of the storage battery 21 of the UPS 11, a capacity calculation step of calculating the capacity of the storage battery 21 in a case where the UPS 11 is in use, a correlation determination step of determining a correlation between the resistance and the capacity of the storage battery 21 based on the resistance calculated in the resistance calculation step and the capacity calculated in the capacity calculation step, and a capacity estimation step of estimating the capacity of the storage battery 21 in a capacity estimation interval P1 between the (x−1)-th use and the x-th use of the UPS 11 based on the correlation. Provided that x is an integer of 3 or more. In the resistance calculation step, the resistance is calculated a plurality of times in the pre-estimation interval P2 before the (x−1)-th use of the UPS 11 and the resistance is calculated in the capacity estimation interval P1. In the correlation determination step, the correlation is determined based on the resistance calculated in the resistance calculation step in the pre-estimation interval P2 and the capacity calculated in the capacity calculation step in at least two uses of the UPS 11 among a first use to the (x−1)-th use. In the capacity estimation step, the capacity of the storage battery 21 is estimated based on the correlation and the resistance calculated in the resistance calculation step in the capacity estimation interval P1.

The capacity of the storage battery 21 in the capacity estimation interval P1 between the (x−1)-th use and the x-th use of the UPS 11 can be estimated by calculating the resistance of the storage battery 21 in the capacity estimation interval P1. Therefore, it is possible to perform the degradation diagnosis of the UPS 11 at any timing without stopping the data center 1. In addition, the correlation between the resistance and the capacity of the storage battery 21 can be determined based on the resistance calculated in the pre-estimation interval P2 and the capacity calculated in at least two uses of the UPS 11 among a first use to the (x−1)-th use. Therefore, it is possible to perform the degradation diagnosis of the UPS 11 without acquiring the data for the degradation diagnosis in advance. Therefore, the maintainability and versatility can be improved.

In addition, the degradation diagnosis device further includes a pulse generation device 15 including a pulse generation unit 26 that generates a pulse signal, and a switch 25 that is switched between an on state and an off state by the pulse signal, the pulse generation device 15 allowing the storage battery 21 to be discharged by switching the switch 25. The resistance calculation unit 32 calculates the resistance of the storage battery 21 based on the measurement results of the current and the voltage of the storage battery 21 in a case where the storage battery 21 is discharged by the pulse generation device 15 in the capacity estimation interval P1. As a result, the degradation diagnosis of the UPS 11 can be easily performed at any timing using the pulse generation device 15.

In addition, the degradation diagnosis device further includes a capacity retention ratio calculation unit 43 that calculates the capacity retention ratio based on the capacity of the storage battery 21 estimated by the capacity estimation unit 42. As a result, it is possible to easily grasp the degradation state of the UPS 11.

In addition, the degradation diagnosis device further includes the display unit 17 on which the estimation result of the capacity of the storage battery 21 by the capacity estimation unit 42 is displayed. As a result, it is possible to easily grasp the degradation diagnosis result of the UPS 11.

### Second Embodiment

Next, a degradation diagnosis device, a degradation diagnosis system, and a degradation diagnosis method according to a second embodiment will be described. Since a basic configuration of the degradation diagnosis device according to the present embodiment is the same as that of the first embodiment, descriptions will focus on differences.

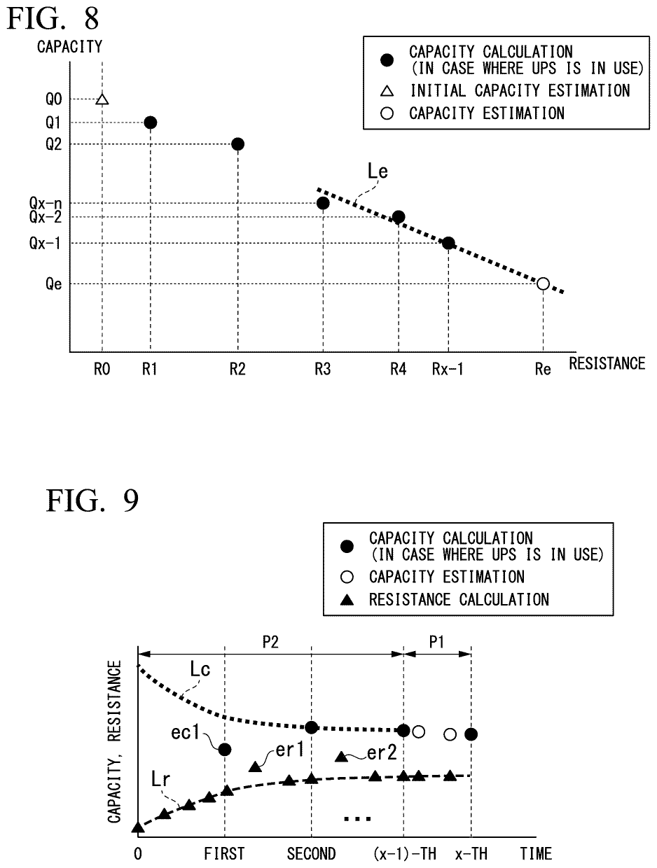

The decrease in the capacity of the storage battery 21 associated with the use of the UPS 11 tends to be large in the initial stage. In the present embodiment, the correlation determination unit 41 determines the correlation by excluding the resistance and the capacitance in the initial stage among the resistance calculated by the resistance calculation unit 32 and the capacity calculated by the capacity calculation unit 33. In the example of FIG. 8, the correlation determination unit 41 determines the correlation (that is, the approximate curve Le) by excluding the resistance R1 and the capacity Q1 of the storage battery 21 in the first use of the UPS 11 and the resistance R2 and the capacity Q2 of the storage battery 21 in the second use of the UPS 11.

As described above, in the present embodiment, the correlation determination unit 41 determines the correlation based on the resistance calculated by the resistance calculation unit 32 in the pre-estimation interval P2 and the capacity calculated by the capacity calculation unit 33 in at least two uses of the UPS 11 among a first use to the (x−1)-th use. Provided that n is an integer of 2 or more and x is an integer of 4 or more. As a result, the diagnostic accuracy of the UPS 11 is improved.

It is noted that n is more preferably 3 or more and x is more preferably 5 or more.

### Third Embodiment

Next, a degradation diagnosis device, a degradation diagnosis system, and a degradation diagnosis method according to a third embodiment will be described. Since the basic configuration of the degradation diagnosis device according to the present embodiment is the same as that of the first embodiment, descriptions will focus on differences.

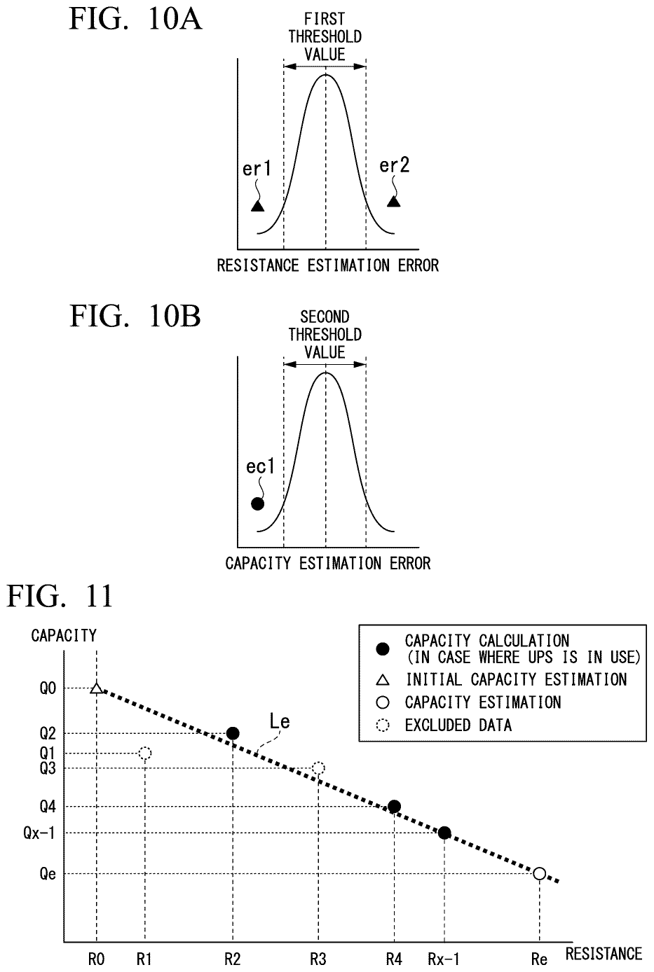

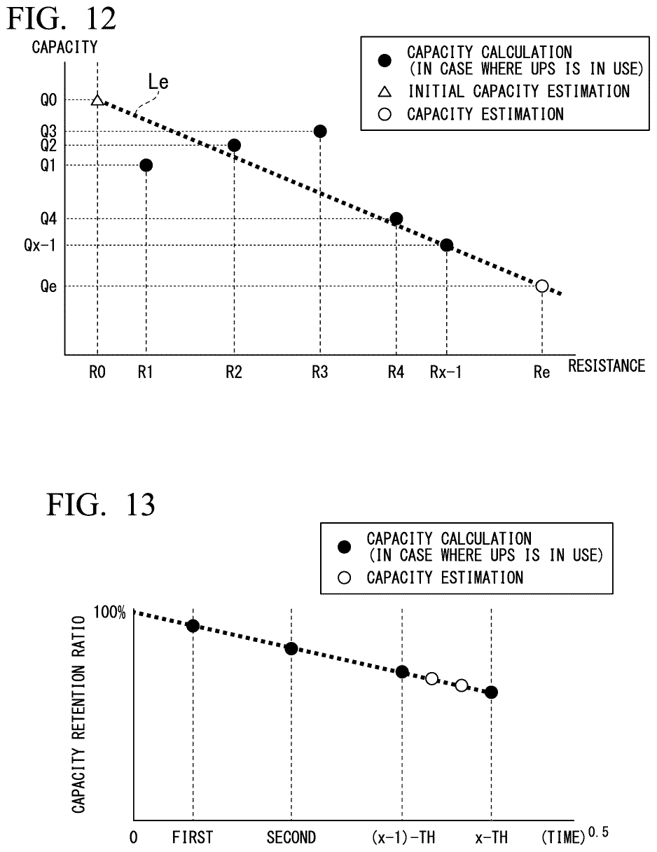

In the present embodiment, the correlation determination unit 41 determines the correlation by excluding the resistance and the capacitance having a large error among the resistance calculated by the resistance calculation unit 32 and the capacity calculated by the capacity calculation unit 33. Specifically, as shown in FIG. 9, the correlation determination unit 41 determines a resistance estimation curve Lr showing a transition of the resistance of the storage battery 21 with the passage of time based on the resistance calculated by the resistance calculation unit 32. The correlation determination unit 41 determines a capacity estimation curve Lc showing a transition of the resistance of the storage battery 21 with the passage of time based on the capacity calculated by the capacity calculation unit 33. The correlation determination unit 41 determines the correlation by excluding the resistance (in FIG. 9, the resistances er1 and er2) in which an error (hereinafter, referred to as a resistance estimation error) with the resistance estimation curve Lr is equal to or more than a first threshold value among the resistances calculated by the resistance calculation unit 32, and the capacity (in FIG. 9, the capacity ec1) in which an error (hereinafter, referred to as a capacity estimation error) with the capacity estimation curve Lc is equal to or more than a second threshold value among the capacity calculated by the capacity calculation unit 33. The first threshold value and the second threshold value are determined as follows, for example. That is, as shown in FIG. 10A, in a case where the resistance estimation error is estimated to appear according to a normal distribution and the standard deviation with respect to the average of the resistance estimation errors represents σ1, the first threshold value is, for example, 2σ1. The first threshold value may be 3σ1. As shown in FIG. 10B, in a case where the capacity estimation error is estimated to appear according to a normal distribution and a standard deviation with respect to an average of the capacity estimation errors is (2, the second threshold value is, for example, 2σ2. The second threshold value may be 3σ2.

In the example of FIG. 11, the correlation determination unit 41 determines the correlation (that is, the approximate curve Le) by excluding the resistance R1 and the capacity Q1 of the storage battery 21 in the first use of the UPS 11 and the resistance R3 and the capacity Q3 of the storage battery 21 in the third use of the UPS 11, among the resistance calculated by the resistance calculation unit 32 and the capacity calculated by the capacity calculation unit 33.

As described above, in the present embodiment, the correlation determination unit 41 determines the resistance estimation curve Lr based on the resistance calculated by the resistance calculation unit 32, and determines the capacity estimation curve Lc based on the capacity calculated by the capacity calculation unit 33. The correlation determination unit 41 determines the correlation by excluding the resistance in which the error with the resistance estimation curve Lr is equal to or more than the first threshold value among the resistances calculated by the resistance calculation unit 32, and the capacity in which the error with the capacity estimation curve Lc is equal to or more than the second threshold value among the capacity calculated by the capacity calculation unit 33. As a result, the diagnostic accuracy of the UPS 11 is improved.

### Fourth Embodiment

Next, a degradation diagnosis device, a degradation diagnosis system, and a degradation diagnosis method according to a fourth embodiment will be described. Since a basic configuration of the degradation diagnosis device according to the present embodiment is the same as that of the third embodiment, descriptions will focus on differences.

In the present embodiment, the correlation determination unit 41 weights the resistance calculated by the resistance calculation unit 32 and the capacitance calculated by the capacity calculation unit 33 based on the capacitive resistance error and the capacity estimation error, and determines the correlation. Specifically, the error E is represented by Expression (6) in a case where the weight is denoted by wᵢ, the capacity (actual measurement value) calculated by the capacity calculation unit 33 at the time of i-th use of the UPS 11 is denoted by Qᵢ, and Qx of Expression (4) is denoted by Q₍ᵣᵢ₎.

$$E = {{\sum }^{n}}_{1} {w}_{i} ( {Q}_{i} - {Q}_{( ri )} ) \qquad ( 6 )$$

That is, from Expression (4), the error E can be represented by Expression (7).

$$E = {{\sum }^{n}}_{1} {w}_{i} ( {Q}_{i} - ( {AR}_{( ri )} + B ) ) \qquad ( 7 )$$

It is noted that the weight wᵢ is represented by Expression (8) using the variance σ² of the error E.

$${w}_{i} = \frac{1}{{σ}^{2}} \qquad ( 8 )$$

The correlation determination unit 41 determines the coefficient A and the constant B in Expression (4) such that the sum of products of the error E and the weight wᵢ is minimized. That is, the correlation determination unit 41 calculates the coefficients A and B such that Expression (6) is minimized, and weights the resistance calculated by the resistance calculation unit 32 and the capacity calculated by the capacity calculation unit 33. The correlation determination unit 41 determines a correlation (that is, an approximate curve Le) based on the weighted resistance and capacity. It is noted that the weighting may be performed in the entire region of the pre-estimation interval P2 or may be performed only for a rear half portion of the pre-estimation interval P2. In a case where the weighting is performed only on a rear half portion of the pre-estimation interval P2, the accuracy of the degradation diagnosis can be improved in a case where the resistance and the capacity of the storage battery 21 are significantly changed in the latter half of the life of the UPS 11 in which the degradation of the UPS 11 progresses.

As described above, in the present embodiment, the correlation determination unit 41 determines the resistance estimation curve Lr based on the resistance calculated by the resistance calculation unit 32, and determines the capacity estimation curve Lc based on the capacity calculated by the capacity calculation unit 33. The correlation determination unit 41 weights the resistance calculated by the resistance calculation unit 32 and the capacity calculated by the capacity calculation unit 33 based on an error between the resistance calculated by the resistance calculation unit 32 and the resistance estimation curve Lr and an error between the capacity calculated by the capacity calculation unit 33 and the capacity estimation curve Lc, and determines the correlation. As a result, the diagnostic accuracy of the UPS 11 is improved.

### Embodiment 5

Next, a degradation diagnosis device, a degradation diagnosis system, and a degradation diagnosis method according to a fifth embodiment will be described. Since a basic configuration of the degradation diagnosis device according to the present embodiment is the same as that of the first embodiment, descriptions will focus on differences.

In the present embodiment, the capacity retention ratio calculation unit 43 calculates the life of the UPS 11 based on the calculated capacity retention ratio.

FIG. 13 is a graph showing a transition of the capacity retention ratio of the storage battery 21 with the horizontal axis representing time to the power of 0.5. As shown in FIG. 13, in a case where the horizontal axis is time to the power of 0.5, the capacity retention ratio of the storage battery 21 tends to decrease linearly. That is, in a case where the elapsed time from the initial state is denoted by t, the capacity retention ratio M can be expressed by Expression (9). C and D are constants and are determined based on the capacity retention ratio calculated by the capacity retention ratio calculation unit 43.

$$M - {Ct}^{0.5} + D \qquad ( 9 )$$

From Expression (9), the life tend of the UPS 11 is represented by Expression (10).

$${t}_{end} = {( \frac{M - D}{C} )}^{2} \qquad ( 10 )$$

For example, in a case where decrease in the capacity retention ratio to 60(%) is assumed as the life of the UPS 11, the life t_{end} of the UPS 11 can be calculated by setting M=60(%) in Expression (10).

The embodiments can be combined, and each embodiment can be modified or omitted as appropriate.

For example, in the above-described embodiment, a case of diagnosing the degradation of the UPS 11 has been described, but the degradation diagnosis device, the degradation diagnosis system, and the degradation diagnosis method of the present disclosure can be applied to the diagnosis of the degradation of a storage battery system other than the UPS.

In addition, the aforementioned control unit 36 includes a computer system inside. A program for implementing functions of each configuration provided by the data center 1 described above may be recorded on a computer-readable recording medium, and by having the computer system read and execute the program recorded on this recording medium, processing in the control unit 36 described above may be performed. In addition, hardware other than the control unit 36 may perform the above-described processing.

Here, the configuration “the computer system reads the program recorded in the recording medium and executes the program” includes installing the program in the computer system. Here, the “computer system” mentioned here includes an operating system (OS) and hardware such as a peripheral device.

In addition, the “computer system” may include a plurality of computer devices connected via a network including a communication line such as the Internet, a WAN, a LAN, and a dedicated line. In addition, the “computer-readable recording medium” refers to a portable medium such as a flexible disk, a magneto-optical disk, a ROM, or a CD-ROM, and a storage device such as a hard disk built in a computer system. In this way, the recording medium on which the program is stored may be a non-transitory recording medium such as a CD-ROM.

In addition, the recording medium also includes an internal or external recording medium that is accessible by a distribution server for distributing the program. In addition, a configuration may be adopted in which the program is divided into a plurality of programs and the plurality of programs are downloaded at different times and then combined in each configuration provided in the data center 1, or the distribution server that distributes each of the divided programs may be different. Furthermore, the “computer-readable recording medium” also includes a medium that holds the program for a certain period of time, such as a volatile memory (RAM) inside the computer system that serves as a server or a client in a case where the program is transmitted via a network. In addition, the program may be a program for implementing some of the functions described above. Furthermore, the program may be a so-called difference file (difference program) capable of implementing the functions described above in combination with a program that has already been recorded on the computer system.

### REFERENCE SIGNS LIST

1 Data center
2 Power system
11 UPS (storage battery system)
12 Server storage (load)
15 Pulse generation device
16 Operation unit
17 Display unit
21 Storage battery
22 BMU (storage battery control unit)
25 Switch
26 Pulse generation unit
31 Acquisition unit
32 Resistance calculation unit
33 Capacity calculation unit
34 Storage unit
35 Degradation amount estimation unit
36 Control unit
41 Correlation determination unit
42 Capacity estimation unit
43 Capacity retention ratio calculation unit

What is claimed is:

1. A degradation diagnosis device that diagnoses degradation of a storage battery system, the degradation diagnosis device comprising:
a resistance calculation unit configured to calculate a resistance of a storage battery of the storage battery system;
a capacity calculation unit configured to calculate a capacity of the storage battery during use of the storage battery system;
a correlation determination unit configured to determine a correlation between the resistance and the capacity of the storage battery based on the resistance calculated by the resistance calculation unit and the capacity calculated by the capacity calculation unit; and
a capacity estimation unit configured to estimate the capacity of the storage battery in a capacity estimation interval between an (x−1)-th use and an x-th use of the storage battery system based on the correlation, where x is an integer of 3 or more,
wherein the resistance calculation unit calculates the resistance a plurality of times in a pre-estimation interval up to the (x−1)-th use of the storage battery system and calculates the resistance in the capacity estimation interval,
the correlation determination unit determines the correlation based on the resistance calculated by the resistance calculation unit in the pre-estimation interval and the capacity calculated by the capacity calculation unit in at least two uses of the storage battery system among a first use to the (x−1)-th use,
the capacity estimation unit estimates the capacity of the storage battery based on the correlation and the resistance calculated by the resistance calculation unit in the capacity estimation interval,
a resistance is calculated by the resistance calculation unit in the pre-estimation interval and a capacity in a use of the storage battery system is calculated by the capacity calculation unit, and
a storage battery of which the correlation is determined by the correlation determination unit is the same as a storage battery of which the capacity is estimated by the capacity estimation unit in the capacity estimation interval.

2. The degradation diagnosis device according to claim 1, further comprising:
a pulse generation device including a pulse generation unit configured to generate a pulse signal and a switch that is switched between an on state and an off state by the pulse signal, the pulse generation device allowing the storage battery to be discharged by switching the switch,
wherein the resistance calculation unit calculates the resistance of the storage battery based on measurement results of a current and a voltage of the storage battery in a case where the storage battery is discharged by the pulse generation device in the capacity estimation interval.

3. The degradation diagnosis device according to claim 1, further comprising:
a capacity retention ratio calculation unit configured to calculate a capacity retention ratio based on the capacity of the storage battery estimated by the capacity estimation unit.

4. The degradation diagnosis device according to claim 1, further comprising:
a display unit on which an estimation result of the capacity of the storage battery by the capacity estimation unit is displayed.

5. The degradation diagnosis device according to claim 1,
wherein the correlation determination unit determines the correlation based on the resistance calculated by the resistance calculation unit in the pre-estimation interval and the capacity calculated by the capacity calculation unit in at least two uses of the storage battery system among n-th use to the (x−1)-th use, where n is an integer of 2 or more and x is an integer of 4 or more.

6. The degradation diagnosis device according to claim 1,
wherein the correlation determination unit determines a resistance estimation curve based on the resistance calculated by the resistance calculation unit, determines a capacity estimation curve based on the capacity calculated by the capacity calculation unit, and determines the correlation by excluding a resistance in which an error with the resistance estimation curve is equal to or more than a first threshold value among the resistances calculated by the resistance calculation unit, and a capacity in which an error with the capacity estimation curve is equal to or more than a second threshold value among the capacities calculated by the capacity calculation unit.

7. The degradation diagnosis device according to claim 1,
wherein the correlation determination unit determines a resistance estimation curve based on the resistance calculated by the resistance calculation unit, determines a capacity estimation curve based on the capacity calculated by the capacity calculation unit, and weights the resistance calculated by the resistance calculation unit and the capacity calculated by the capacity calculation unit based on an error between the resistance calculated by the resistance calculation unit and the resistance estimation curve and an error between the capacity calculated by the capacity calculation unit and the capacity estimation curve, to determine the correlation.

8. A degradation diagnosis system comprising:
the degradation diagnosis device according to claim 1; and
the storage battery system,
wherein the storage battery system includes a storage battery and a storage battery control unit configured to control the storage battery.

9. A degradation diagnosis method for diagnosing degradation of a storage battery system, the degradation diagnosis method comprising:
a resistance calculation step of calculating a resistance of a storage battery of the storage battery system;
a capacity calculation step of calculating a capacity of the storage battery during use of the storage battery system;
a correlation determination step of determining a correlation between the resistance and the capacity of the storage battery based on the resistance calculated in the resistance calculation step and the capacity calculated in the capacity calculation step; and
a capacity estimation step of estimating the capacity of the storage battery in a capacity estimation interval between an (x−1)-th use and an x-th use of the storage battery system based on the correlation, where x is an integer of 3 or more,
wherein in the resistance calculation step, the resistance is calculated a plurality of times in a pre-estimation interval up to the (x−1)-th use of the storage battery system and the resistance is calculated in the capacity estimation interval,
in the correlation determination step, the correlation is determined based on the resistance calculated in the resistance calculation step in the pre-estimation interval and the capacity calculated in the capacity calculation step in at least two uses of the storage battery system among a first use to the (x−1)-th use,
in the capacity estimation step, the capacity of the storage battery is estimated based on the correlation and the resistance calculated in the resistance calculation step in the capacity estimation interval,
a resistance is calculated by the resistance calculation step in the pre-estimation interval and a capacity in a use of the storage battery system is calculated by the capacity calculation step,
a storage battery of which the correlation is determined by the correlation determination step is the same as a storage battery of which the capacity is estimated by the capacity estimation step in the capacity estimation interval.

10. The degradation diagnosis device according to claim 1, wherein
the storage battery system is connected to a load via a switch, and a first electric power is supplied from the storage battery system to the load when the switch is in an on state,
when the storage battery system is not in use, the first electric power is not supplied from the storage battery system to the load, and an second electric power is supplied from a power system to the load, and
when the storage battery system is in use, the second electric power is not supplied from the power system to the load, and the first electric power is supplied from the storage battery system to the load.
